(19) United States
(12) Patent Application Publication
(10) Pub. No.: US 2026/0113917 A1
(43) Pub. Date: Apr. 23, 2026

(54) MAGNETIC FIELD CANCELLATION SYSTEM

(71) Applicant: SAFEFIELDS TECHNOLOGIES LTD., Herzliya (IL)

(72) Inventors: Shaul SHULMAN, Ramat Gan (IL); Oded EINAT, Herzliya (IL)

(73) Assignee: SAFEFIELDS TECHNOLOGIES LTD., Herzliya (IL)

(21) Appl. No.: 18/844,183

(22) PCT Filed: Mar. 6, 2023
(86) PCT No.: PCT/IL2023/050225

§ 371 Date: Sep. 5, 2024

(30) Foreign Application Priority Data
Mar. 8, 2022 (IL) 291200

(51) Int. Cl. H05K 9/00; B60L 3/00; G01R 19/00

(52) U.S. Cl. CPC H05K 9/0071; B60L 3/0061; G01R 19/0007; G01R 19/0092; B60L 2240/429; B60L 2270/147

(57) ABSTRACT

Systems, methods, and computer program products are disclosed for cancelling a magnetic field in a passenger region of a vehicle. Cancelling a magnetic field in a passenger region of a vehicle includes a chassis, a passenger region of the vehicle, a current carrying loop (CCL) configured to carry electricity during vehicle operation, thereby generating a magnetic field configured to radiate toward the passenger region, a sensor associated with the CCL for sensing current passing through the CCL, an electrical wire loop spatially aligned with a physical path of the CCL, and a circuit configured to: receive current sensing data from the sensor, and based on the current sensing data, determine a cancellation electrical current for providing to the electrical wire loop in order to cause a cancelling magnetic field, thereby at least reducing magnetic radiation from the CCL to the passenger region.

### TECHNOLOGICAL FIELD

The present disclosure relates to systems and method for cancellation of magnetic field in a selected region. The present disclosure specifically relates to cancellation of magnetic field in vicinity of electrical systems such as in hybrid or electric vehicles.

### BACKGROUND

Electromagnetic radiation, and general electromagnetic fields, surrounding human environment is increasing with the use of electrical tools. Various scenarios and applications may require the ability for nullifying or significantly reducing electromagnetic fields (EMF) or electromagnetic radiation in certain regions. Specific such scenarios relate to electric and electric hybrid vehicles. Such electric and hybrid vehicle utilize electric currents for operation of the vehicles' motor and other systems, while passengers may spend significant time within the vehicle exposed to EMF within the vehicle.

According to medical research, low frequency magnetic radiation is believed to cause long-term adverse health effects. In the example of electric automobiles/vehicle, reducing the EMF radiation in the area of the passengers' seats may be desired.

### GENERAL DESCRIPTION

Electrical systems typically utilize transmission of electrical currents from a power source to power user, or load. The electrical current may generally be transmitted through electric wires the extend in space between the power source and load. The flow of current in such electric wires generates magnetic fields is based on Ampere's circular low indicating, in its differential form that ∇×B=μ₀J. In this format, B is the magnetic field, ∇× is curl differential operator, μ₀ is free space permeability, and J is the current density.

To properly transmit electricity, electric transmission wires between power source and load create a closed circuit. The transmission lines/wires include two or more separated lines/wires connected respectively to positive and negative (or phase and zero) connection of the power source and transmit the electrical current to the load and back to the power source. Accordingly, an electric connection between power source and a load utilizes at least a pair of electric lines referred to herein as power and zero lines, although may also include positive and negative potential or phase and zero/ground connections. Further, as described in more detail below, in some configurations, only a single power line may be used, transmitting electric potential to a load. In these configurations, the load is generally connected to an effective ground connection, providing the “zero” line passing through electricity conducting elements, e.g., vehicle chassis parts.

To avoid generating magnetic fields, the pair of electric lines may typically be twisted between them along a path between physical position of the power source and position of the load. However, in accordance with physical and mechanical constraints in electric line arrangement and/or electric connection of the load, the twisted pair of wires may separate at certain point causing the different (e.g., plus and minus) lines to take different paths. This results in an effective current carrying loop extending from the split point of the twisted pair, along the plus wire section to respective connection of the load, through a current path within the load, and from the respective second connection of the load through the minus wire section to the split point of the twisted pair. Transmission of electrical current through such a loop arrangement generates magnetic field, and may generate electromagnetic radiation, in accordance with frequency of AC components of the current.

The present disclosure provides a technique for eliminating, or at least significantly reducing magnetic fields within a selected region. The present technique utilizes determining, or providing, data on arrangement of electrical wires transmitting currents between one or more power source units and one or more load or power consumption units. Determining arrangement of one or more current carrying coils/loops, formed by wire arrangement causing electrical current to flow in an effectively closed loop shaped path. Providing one of more field cancellation unit, formed by a current carrying loop, amplifier module and sensing module to cancelling magnetic field generated by current passing through the effectively closed loop shaped path. Providing the current carrying coil/loop along a path corresponding with a respective effectively closed loop shaped path of electric wires and utilizing the sensing module for providing data on electrical current transmitted in the respective effectively closed loop shaped path. The current flowing in the current carrying coil is thus opposite to the current flowing in the respective effectively closed loop shaped path, generating opposite magnetic field that effectively cancels, or at least significantly reduces the magnetic field generated by the electrical system.

Thus, according to a broad aspect, the present disclosure provides a method for use in reducing magnetic fields generated by an electric system, the method comprising:
determining one or more current carrying loops in electric wiring of the electric system;
providing, for at least one of said one or more current carrying loop, a parallel electrical wire loop, generally overlapping physical path of said at least one current carrying loop;
connecting said parallel electrical wire loop with a power supply system, comprising at least one current sensor;
operating said at least one current sensor to provide sensing data indicative of current passing in said at least one current carrying loop;
utilizing said sensing data and operating said power supply system for transmitting electrical current in said parallel electrical wire loop, wherein said electrical current being opposite in direction to current passing in said at least one current carrying loop, thereby eliminating, or at least significantly reducing magnetic fields generated by current passing in said at least one current carrying loop.

According to some embodiments, transmitting electrical current in said parallel electrical wire loop comprises providing current that is equal (up to acceptable measurement variation) to current passing in said at least one current carrying loop. Additionally, phase/direction of the current transmitted through said parallel electrical wire loop may preferably be 180° (i.e., opposite in direction) with respect to current detected in the at least one current carrying loop, up to acceptable measurement variation.

According to some embodiments, utilizing said sensing data may comprise determining AC components of the current passing in said at least one current carrying loop and generating electrical current being opposite in phase and of similar amplitude with respect to said AC components for transmitting in said parallel electrical wire loop.

According to some embodiments, said electric system may comprise an electric or electric hybrid vehicle.

According to another broad aspect, the present disclosure provides a system for use in cooperation with an electric system comprising one or more current carrying loops, the system comprising:
a control unit;
an electrically conductive wire loop arranged in parallel to at least one of said one or more current carrying loops and being generally conforming to a physical path thereof;
a current sensor arranged for determining sensing data on electrical current passing in said at least one of said one or more current carrying loops and transmitting said sensing data to the control unit;
the control unit is configured for transmitting cancellation electrical current through said conductive wire loop, said cancellation electrical current having opposite direction to said current passing in said at least one of said one or more current carrying loops, to thereby eliminate, or at least significantly reduce magnetic field generated by current passing in said at least one current carrying loop.

According to some embodiments, the control unit may comprise a selected frequency filter configured for filtering said sensing data to provide filtered data indicative of selected frequency components of current flowing in said at least one of said one or more current carrying loops, said control unit being operated for transmitting electrical current corresponding and opposite to said frequency components of the sensing data.

According to some embodiments, the control unit may comprise a high-pass filter configured for filtering said sensing data to provide filtered data indicative of AC components, said control unit being operated for transmitting electrical current corresponding and opposite to said AC components of the sensing data.

In some embodiments the frequency filter may be a band-pass filter configured for transmitting sensing data within a selected one or more frequency ranges. This configuration may be used for providing cancellation field for a selected frequency band of magnetic fields.

According to some embodiments, the current sensor may be formed as a current clamp sensor having phase shift below a predetermined threshold. In some embodiments, the current sensor may be a field probe positioned for sensing magnetic field. The field probe may be place at vicinity to one or more current carrying lines of the current carrying loop to provide sensing data indicative of current flow within said line.

According to some embodiments, the at least one current carrying loop may comprise a loop portion passing though electrical components of said electric system.

According to some embodiments, the electric system is an electric or hybrid electric vehicle.

According to some embodiments, a portion of said at least one current carrying loop comprises one or more portions of vehicle body.

According to some embodiments, the system may further comprise a difference current sensor configured for providing said control unit with difference sensing data indicative of difference between current transmitted in said electrically conductive wire loop and the respective current carrying loops combined; said control unit is configured for adjusting said cancellation electrical current to minimize said difference sensing data.

According to yet another broad aspect, the present invention provides a system for use in cooperation with an electric or hybrid electric vehicle, having electrical wiring arrangement comprising one or more current carrying loops, the system comprising:
a control unit;
an electrically conductive wire loop arranged along at least one of said one or more current carrying loops and being generally conforming to a physical path thereof;
a current sensor arranged for determining sensing data on electrical current passing in said at least one of said one or more current carrying loops and transmitting said sensing data to the control unit;
the control unit is configured for transmitting cancellation electrical current through said conductive wire loop, said cancellation electrical current having opposite direction to said current passing in said at least one of said one or more current carrying loops, to thereby eliminate, or at least significantly reduce magnetic field generated by current passing in said at least one current carrying loop.

According to some embodiments, selection of one or more current carrying loops may be based on proximity of the current carrying loop to passenger region of the vehicle, and/or level of magnetic or EMF radiation generated by the current carrying loop and radiating toward passenger region of the vehicle.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A and 1B illustrate a system utilizing electrical elements and including one or more current carrying loops, FIG. 1A illustrates the system and FIG. 1B illustrates the system with magnetic field cancellation system according to some embodiments of the present disclosure;

FIG. 2 exemplifies configuration of magnetic field cancellation system according to some embodiments of the present disclosure;

FIG. 3 exemplifies magnetic field cancellation system configuration set for optimizing output current according to some embodiments of the present disclosure;

FIG. 4 is a flow chart diagram exemplifying technique for cancelling magnetic fields according to some embodiments of the present disclosure;

FIG. 5 shows experimentally measured magnetic field in a parking vehicle with a system according to the present disclosure turned off and on;

FIG. 6 shows experimentally measured magnetic field in a vehicle driving at slow speed with a system according to the present disclosure turned off and on;

FIG. 7 shows experimentally measured magnetic field in a vehicle during drive in city environment with a system according to the present disclosure turned off and on; and

FIG. 8 shows experimentally measured magnetic field in a vehicle during drive intercity road with a system according to the present disclosure turned off and on.

### DETAILED DESCRIPTION OF EMBODIMENTS

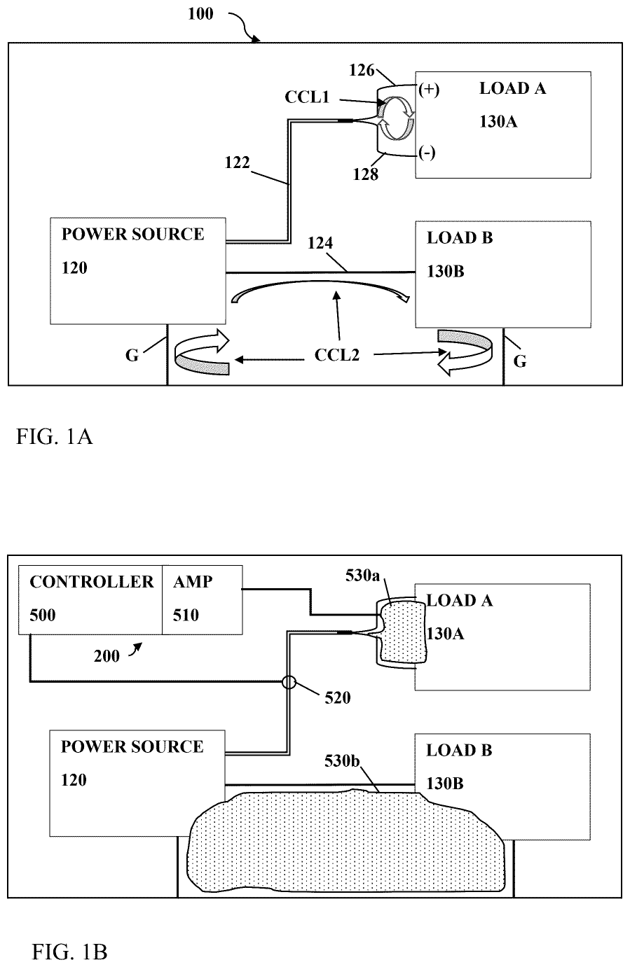

As indicated above, the present disclosure provides a system and a technique for cancelling magnetic fields generated in an electrical system. Reference is made to FIGS. 1A, schematically illustrating a system 100, generally using electric power for operation of one or more load units 130A and 130B. The electrical power is provided from a power source 120, e.g., battery pack/array, and transmitted to the load 130 via electrical transmission lines 122, 124, 126, 128 and/or ground connection G. FIG. 1B illustrates the system 100, with addition of magnetic field cancellation system 200 according to some embodiments pf the present disclosure.

As shown in FIG. 1A, electrical power is transmitted from power source 120 to the load units 130A and 130B using electrical transmission lines carrying electrical current. For example, electrical transmission line 122 is formed of a twisted cable pair carrying current to and from power source 120 to load unit 130A. In various situations, resulting from mechanical or electrical constraints, the twisted cable 122 may split to first and second cables 126 and 128, directed to first and second, or plus and minus, contacts of the load unit 130A. In this connection and in accordance with electrical signal scheme used by system 100, the first and second cables 126 and 128, may have various representations such as plus/minus, phase/zero, etc. In general, irrespective of the specific electrical signal scheme, current that is transmitted to the load in one of the cables, is transmitted back to the power source 120 in the other cable.

It should be noted that power source 120 may be an AC or DC power source. For example, in a typical electric or hybrid electric vehicle, the power source 120 includes one or more battery arrangements providing DC electrical power. However, in accordance with power consumption configurations, and/or following the use of rectifying circuits. The output electrical power may generally include AC components.

The current path formed by first and second cables 126 and 128, generates an effective current carrying loop (CCL), where the current transmitted to load A 130A circles in the loop CCL1. Current flow within the loop generates magnetic field in accordance with magnitude and variation frequency of the current.

Another example illustrated in FIG. 1A, includes a single power transmission line 124 extending between the power source 120 and load unit 130B. In such configuration, the load unit 130B and power source 120 are further connected to a common ground connection G, thereby closing the electric circuit. The common ground may for example be frame or chassis of the system 100. As a result, the electrical current is transmitted through power line 124, and the common ground connection G, generating a current carrying loop CCL2.

In this connection it should be noted that current carrying loops CCL1 and CCL2 are illustrated together for simplicity, and to exemplify main types of current carrying loops that can be found in electrical systems. Further, it should be noted that the power source 120 is illustrated herein as a single power source, however, in a typical system different loads and accordingly different CCLs may be connected to one or more different power sources, providing selected and not specifically similar output voltage and current characteristics. Also, it should be understood that a CCL may be formed at any point along electrical conduction lines and may be associated with separated electric contacts at the power source 120, distance between electric contacts at the load 130, both or any other configuration where the electric lines are spatially separated generating a CCL.

Electrical currents flowing in a loop pattern enhance the magnetic fields generated by the moving charges. Generally, direct current (DC) generates static magnetic field, while alternating current (AC) portions cause variations in the magnetic field, associated with electromagnetic radiation having frequency that corresponds with the AC frequency of the currents. To eliminate, or at least significantly reduce magnetic fields and/or electromagnetic radiation in selected region in vicinity of the electrical system 100, the present disclosure provides a system and technique utilizing one or more parallel electrical wire loops. The one or more parallel electrical wire lops are placed to overlap with one or more CCLs identified in the electrical system 100. More specifically, the one or more parallel electrical wire loops may be placed to align with conductors of the one or more CCLs to spatially conform with the respective CCLs. Current transmission in the parallel electrical wire loops is determined to be opposite in direction, and preferably as close in amplitude (current level), to current flowing in the respective CCL, to effectively cancel the magnetic fields generated by the current flowing in the CCL. This is illustrated in FIG. 1B, showing additional parallel electrical wire loops 530a and 530b placed to be generally overlapping with current carrying path of CCL1 and CCL2. In other words, parallel electrical wire loops 530a and 530b are positioned to spatially conform to physical path of the respecting CCLs, such that the CCL and the respective parallel electrical wire loops 530 act as a common source for magnetic field.

As illustrated in FIG. 1B, parallel electrical wire loops 530a and 530b are placed to overlap with path of electrical current defining current carrying loops CCL1 and CCL2. The parallel electrical wire loop 530a and 530b are connected to an electrical control system 200 including at least an amplifier 510, and sensor 520. System 200 may also include a controller 500 enabling processing and control for proper system operation. For simplicity of the illustration, system 200 is illustrated being connected to parallel electrical wire loop 530a only. It should however be understood that parallel electrical wire loop 530b is also connected to a corresponding system 200, which may be the same or a separated control system. Further, it should be understood that each parallel electrical wire loop 530, and the respective control system 200 is associated with respective one or more current sensors 520, placed for sensing current in selected current transmission lines feeding the corresponding CCL.

The current sensor 520 is positioned to provide sensing data indicative of electrical current transmitted in one or more current carrying lines that feed the respective current carrying loop. Generally, the current sensor 520 may be any type of current sensing unit capable of generation real-time output data about electrical current passing through a respective current carrying wire/line, such as current clamp sensor. In some configurations, current sensor 520 may be replaced by a field probe positioned for determining magnetic field at a selected location nearby a current carrying line. Preferably, to allow cancellation of high-frequency EMF, sensor 520 is generally a current sensor configured for generating sensing data indicative of current and current variations. The sensor may wide band sensor having a known frequency response function, such as flat phase response function. Alternatively, the controller 500 may be adapted for compensating for variation in frequency response function of the sensor 520, e.g., when the response function is not known. This may be used to provide phase accurate sensing data indicative of AC current variations and enable cancellation of EMF generated by varying electrical currents. In some configurations, the current sensor 520 may be configured with a phase shift, in one or more selected frequency ranges, being below a predetermined threshold. This configuration enables selection of current sensor based on frequency range of operation of electrical system 100, and range of frequencies in which EMF generated by the respective CCL is to be canceled. The current sensor 520 may be an electrical transducer suitable for measuring AC currents such as high-speed transients, pulsed currents of a power device, or power line sinusoidal currents in selected one or more frequency ranges. For example, the current sensor 520 may be a Rogowski coil current probe or other suitable current probes.

The sensor 520 is configured to provide current sensing data to an amplifier unit 510. The amplifier 510 is configured to receive the current sensing data and transmit corresponding electrical current to the parallel electrical wire loop 530 connected thereto. Electrical connections between amplifier 510, parallel electrical wire loop 530, and sensor 520 are configured to provide the output current from amplifier 510 is opposite in direction to detected current passing the in respective CCL. Additionally, the amplitude of the current transmitted in parallel electrical wire loop 530 is substantially similar to amplitude of the current detected in the respective CCL. More specifically, given that the sensor 520 provides sensing data indicative of current I(t), the amplifier 510 is operated to provide output cancelling current being −kI(t) where k˜1. Due to this configuration, parallel electrical wire loop 530 is operated to generate EMF that is equal in magnitude and opposite in direction to EMF generated by the respective CCL, and effectively cancels the CCL generated EMF. Accordingly, amplifier 510 may be selected in accordance with frequency response function thereof, to provide output signal having known phase relation with input sensing data on detected current. The phase relation may preferably be flat, allowing similar or opposite phase of the output signal. As indicated above, frequency range in which the frequency response function is of flat phase may be selected in accordance with frequency range of current variation in system 100, to thereby enable effective cancellation of EMF generated by the respective CCL. Generally, the amplifier 510 may be formed as a two-stage amplifier or more, including a variable gain amplifier stage and a power amplifier stage. Operation of the variable gain amplifier enables adjustment of amplification parameter k to provide k˜1, i.e., minimize the function |k−1|.

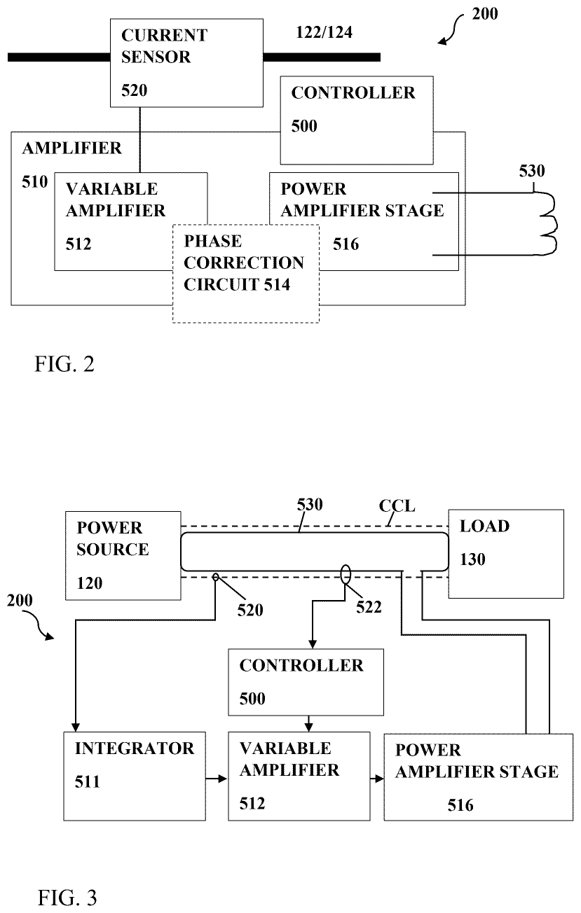

An exemplary configuration of magnetic field cancellation system 200 according to some embodiments of the present disclosure is illustrated in FIG. 2. As shown, the system includes a current sensor 520 positioned to detect current in one or more electrical lines 122/124 feeding a selected CCL, and an amplifier 510. The system 200 may also include a controller 500 providing processing and user interface for operation of the system. Amplifier 510 may be a two-stage amplifier including a first variable gain amplifier 512 having known phase shift for selected frequency range, and a power amplifier stage 516. In some configurations, in accordance with known phase shift of the variable gain amplifier 512, the amplifier unit 510 may also include a phase correction circuit 514 configured to align phase of amplified signal to phase of current detected by the sensor 520. The power amplifier stage 516 provides output current, that is generally similar in magnitude, and opposite in phase to current detected by sensor 520. The output current is directed to flow through parallel electric wire loop 530 position as described herein to substantially overlap a selected CCL in the system, to thereby cancel magnetic field generated by the CCL.

For example, the amplifier unit 510 may be selected in accordance with one or more requirements. An initial requirement is based on phase shift. Accordingly, the amplifier should enable operation with predetermined, and preferably zero phase shift. The amplifier 510 may be selected having one or more electrical requirements as indicated in table 1.

TABLE 1

| Input Frequency range | 10 Hz to 5 Khz | |
|---|---|---|
| Input voltage | 1-100 mVrms (DC up to 1 Volt) | |
| Input impedance | >1 | Kohm |
| Floating input (h and L) | <100 | Vdc |
| to DC supply | | |
| AC current output | max 5 Apeak | |
| Maximum output voltage | 12 | V |

| | |
|---|---|
| Antenna resistance | 0-2 Ohm, 10 microHy to 500 microHy |
| Vout (DC) | below 100 mV |
| Floating output (h and L) | up to 500 Vdc |
| to DC supply | |

Generally, the amplifier may operate in amplification range with 1-50 mVrms input voltage and 0.1-5 Arms output current, total harmonic distortions below 5% and to allow phase shift below 1 degree within the selected frequency range. The amplifier 510 may operate using single or dual power supply in the range of 10-26V (DC). The amplifier 510 may include an undervoltage protection and may be configured with 2 supply lines with internal sum.

Although, presence of static magnetic field is generally not desired, cancelling of such static magnetic fields are typically of less interest compared to varying magnetic fields, or EMF, typically due to possible health hazards known to be associated with varying EMF. To this end, scoring of CCLs may be determined in accordance with amplitude and frequency of current variations. Further, the sensing data, and amplifier may be configured for providing the parallel electric wire loop with current pattern that is directed at eliminating AC components of the CCL current, to eliminate, or at least significantly reduce EMF emitted by the CCL. In some configurations, the sensor 520 is configured to provide sensing data indicative of AC components of electric currents at frequency ranges between 10 Hz and 5 KHz. The amplifier 510 may thus be configured for operating in the selected frequency range, considering possible phase shifts in the selected frequency range.

Operation for canceling magnetic field generated by AC components of electric current also allows energy saving as it omits the need to transmit high DC current to counteract DC components of the CCL current. To this end, the amplifier 510 may be associated with a high-pass filter adapted for removing DC components from the sensing signal and transmit AC components of a selected frequency range, e.g., exceeding a selected threshold. This configuration is used for reducing EMF components over the slow-varying magnetic fields, thereby operating with reduced energy and reduced current transmission in the parallel electric wire loop. Further, as described in more details below, the power required for canceling magnetic field using the present technique relates to the current used multiplied by the load of the parallel electric wire loop 530. Proper selection of the loop 530 parameters, such as resistance and inductance enable to minimize the operation power of the system.

Further, in some embodiments, the amplifier 510 may be associated with a band-pass filter adapted for filtering selected frequency components from the sensing signal. This enables transmission of AC components within a selected frequency band to cancel selected frequency band of magnetic fields. In some additional configurations, the amplifier 510 may be associated with a low-pass filter. This may be used for canceling the relatively strong, low frequency magnetic fields.

As indicated above, current cancelling system 200 according to the present disclosure may also include a controller 500. Controller 500 may generally include a processing utility, memory utility and user interface module, and is configured to provide controlling functions to system 200. Controller 500 may thus include a processor and memory circuitry (PMC) operatively connected to a hardware-based I/O interface controlling operation of sensor 520 and amplifier 510. Controller 500 may be configured to provide processing necessary for operating the system 200 as further detailed herein and comprises a processor (not shown separately) and a memory (not shown separately). The processor of controller 500 can be configured to execute several functional modules in accordance with computer-readable instructions implemented on a non-transitory computer-readable memory comprised in the controller 500. Such functional modules are referred to hereinafter as comprised in the controller 500.

In some embodiments, sensing data, collected by current sensor 520 may be transmitted to controller 500 for processing and determining current pattern to be transmitted, by amplifier 510, through the parallel electrical wire loop 530. Such processing may be used in configurations where the current that is provided to the load follows selected patterns and thus current parameters are predictable. In other configurations where the current patterns may vary without a distinct predictable pattern, analog operation may be preferred. In analog operation, the sensed current signals are amplified and transmitted in opposite phase through the parallel electrical wire loop 530.

The electrical system 100, may generally be any system that utilizes electrical power for its operation. In some embodiments of the present disclosure, system 100 may be a vehicle, such as electric or hybrid electric vehicle. In such vehicles, passengers may spend long time periods within the vehicle, being generally exposed to high magnetic fields and EMF generated by the vehicle's electrical system. The present technique utilizes one or more current parallel electrical wire loop placed in selected locations to cancel, or at least significantly reduce electromagnetic fields applied on the passengers in the vehicle.

An additional example is illustrated in FIG. 3 showing system 200 for cancellation of magnetic field. The system 200 includes a parallel electric wire loop 530, illustrated as being placed to overlap with CCL (marked in dashed lines) extending between a power source 120 and load 130. The system 200 utilizes a current sensor 520 positioned to provide data on current feeding the CCL (the sensor may be placed along the CCL or along electric lines feeding the CCL as exemplified above). The current sensor provides current data to an integrator 511 configured to operate the variable gain amplifier 512 (or to provide current data directly to the amplifier 512). When output current is transmitted by the power amplifier stage 516, the controller may operate to adjust the gain for optimized cancellation of the magnetic field. To this end, an additional current sensor 522 may be placed to measure the total current transmitted through the CCL and the parallel electric wire loop 530, and to provide current data to the controller 500. Controller 500 is thus configured to adjust gain and phase levels to minimize the current detected by sensor 522 being combined CCL and loop 530 currents. Accordingly, sensor 522 is configured to provide difference sensing data indicative of difference in currents transmitted through the CCL and the respective loop 530. This configuration provides a simple feedback system for accurately cancelling magnetic fields by providing opposite current to overlapping loops.

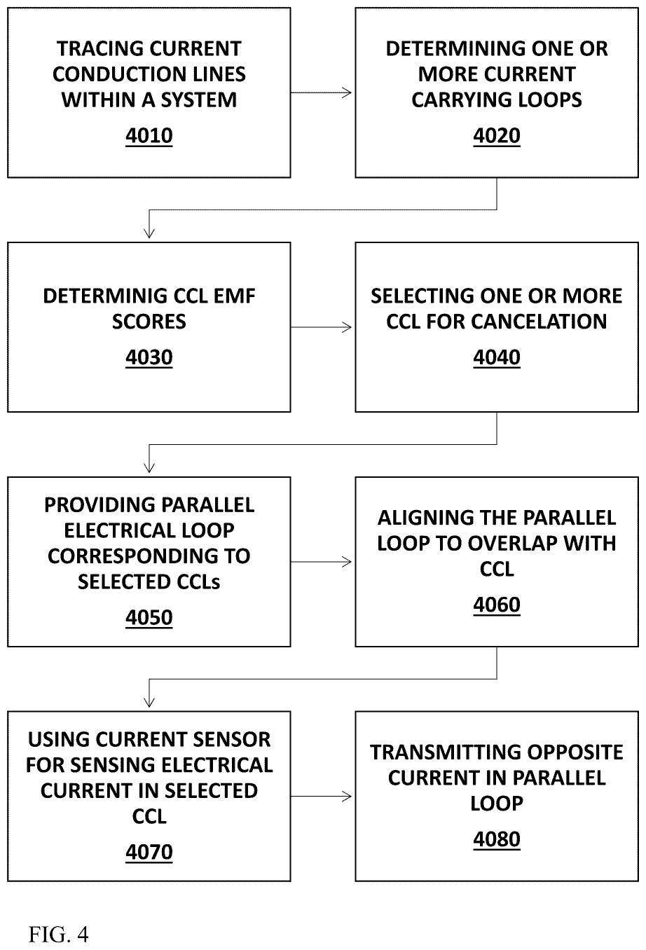

In this connection, the present disclosure provides a method for use in reducing magnetic and electromagnetic fields within a selected region, of fields generated by an electric system. Reference is made to FIG. 4 showing a flow chart illustrating operational actions associated with the methos of the present disclosure. As shown, the technique includes determining one or more current carrying loops in electric transmission lines of the system. This may include tracing current conduction lines within the system 4010 and determining one or more CCLs 4020. As typical electric system may include a number of electrical components (loads), and may thus include a plurality of CCL, the technique may include determining CCL EMF score 4030. This may include determining a selected set of parameters associated with current and magnetic field generated by the respective CCL. For example, the score may include parameters such as magnitude of current, amplitude and frequency of typical current variations (AC components) transmitted in the respective CCL, pattern of magnetic field and EMF generated by the CCL, and spatial area affected by the fields radiated by the CCL. As known, magnitude of DC current components determined magnitude of statis magnetic fields generated by the CCL. The amplitude and frequency of current variations (AC current components) determine frequency and magnitude of EMF generated by the CCL. Preferably, High amplitude of AC current components may receive higher score. Further CCLs placed in vicinity of passenger area, radiating toward passenger area, and/or operate with high current may receive higher score over others. The scoring may be used to determine which CCLs generate high magnetic fields and thus should be treated according to the present disclosure with a parallel electric wire loop. However, in accordance with predetermined number of CCLs to handle, the number of parallel electrical wire loops may be selected in accordance with number of CCLs in the system selected for cancellation 4040.

As indicated above, for each selected CCL, the technique includes providing a respective parallel electrical wire loop 4050. The parallel electrical wire loop is aligned to spatially overlap/conform with the respective CCL 4060. In this connection, the CCLs may be direct CCL formed of current transmission lines such as CCL1 in FIG. 1A. However, some CCLs may include chassis portions such as CCL2 in FIG. 1A. In this case, the parallel electrical wire loop may generally be aligned to overlap with an approximation of the minimal path of current transmission through the chassis.

For each parallel electrical wire loop, the technique includes using a corresponding sensor, for determining sensing data on current passing in the respective CCL 4070. The sensor may be place at any convenient location along current transmission lines that feed the respective CCL. The sensing data is collected and used for generating electrical current of opposite phase, and preferably similar amplitude, to be transmitted in the parallel electrical wire loop 4080. The opposite current transmitted in the parallel electrical wire loop generated electromagnetic field that is opposite in direction to that generate by the respective CCL, and thus reduces the total EMF magnitude, and preferably cancels it.

It should be noted that the electrical current transmitted through the parallel electrical wire loop is as close as possible, and preferably equal in magnitude to that transmitted in the respective CCL. However, as this electrical current is not used for operating one or more load units as the current transmitted in the CCL, the power transmitted in the parallel electrical wire loop may be very small. More specifically, the system 200 as described herein may be optimized for selected power use. This is as the measurable parameter for cancelation of magnetic fields is associated with current flowing through the respective loop 530, while the voltage provided for transmission of such current may be selected in accordance with resistance of the loop 530 to not exceed a selected power threshold. More specifically, the present technique relies on transmission of current through the parallel electric wire loops 530 that need not produce “power” but rather to produce magnetic field. Accordingly, the power consumption of the system is generally proportional to the current generated times the load through the parallel electric wire loops 530. The load of the loop 530 may be selected to be very low (i.e., just the resistance and inductance of the coils) to thereby minimize the used power.

Generally, effective cancellation of EMF generated by a CCL in the electrical system 100 is determined by spatial overlap between the CCL and the respective parallel electrical wire loop, as well as by relation between current passing in the CCL and the respective cancellation electrical current. To this end, the present technique may rely on spatial overlap between the parallel electrical wire loop and the respective CCL. Generally, using standard techniques, considering complexity of CCL path, a 10-25% variation in overlap may be acceptable for limiting generation of EMF. Generally, the parallel electrical wire loop is configured to spatially conform to physical path of the CCL up to acceptable variations due to physical constraints. Moreover, accurate overlap between the parallel electrical wire loop and the respective CCL provides for optimized cancellation of magnetic field, while any variation in overlap may result in reduced cancellation of the magnetic fields. An acceptable overlap is generally sufficient to reduce magnetic fields to World Health Organization acceptable levels. Further, in typical electrical system, such as electric of hybrid electric vehicle, load units that are high current users are typically connected using a pair of electric transmission lines, resulting is configuration associated with CCL1 in FIG. 1B, rather than CCL2 where current is partially transmitted through chassis of system 100. This arrangement enables improved overlap and increased efficiency in EMF cancellation.

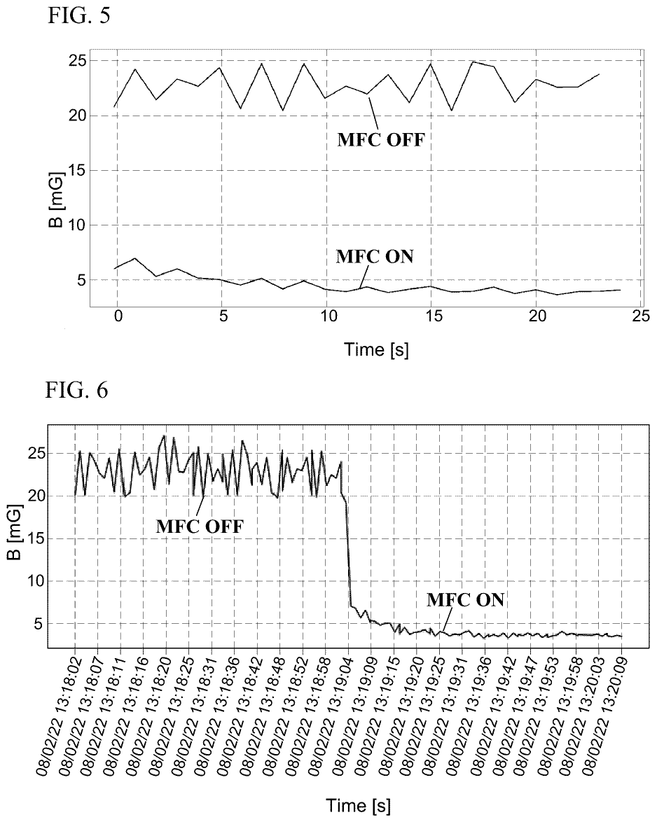

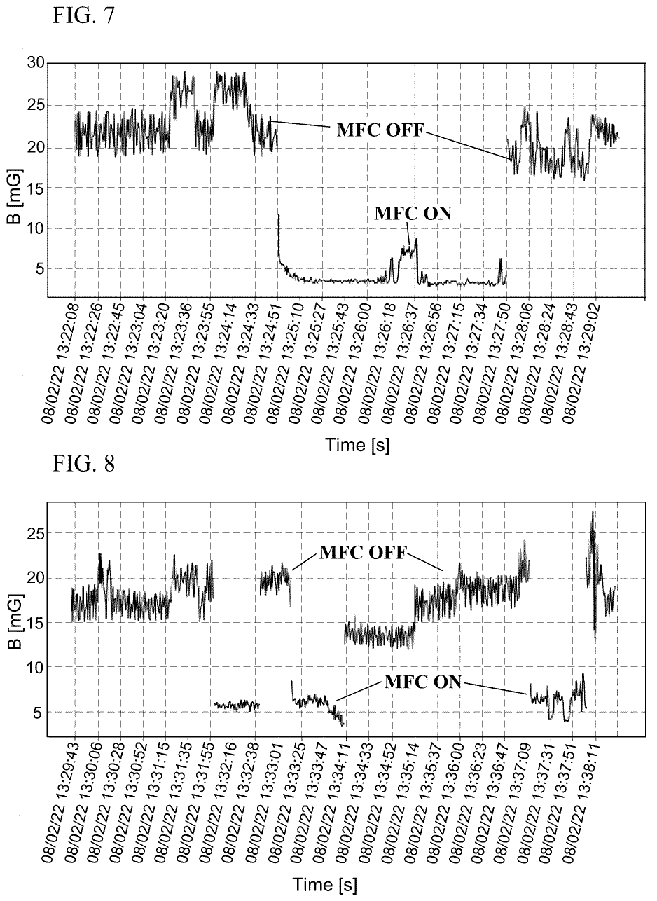

The present technique was tested using a Hyundai Ioniq hybrid electric vehicle, commercially available. The vehicle includes two main electrical systems including a low voltage (e.g., 12V) electrical wiring including ground connection via the vehicle chassis, and a high voltage electrical wiring where the battery connections are separated generating a CCL between the positive and negative plugs. Magnetic field in the passenger compartment of the vehicle was measured using a magnetic field measurement unit, e.g., Tenmars TM-192\D triaxial magnetic field meter, during vehicle operation with the magnetic field cancellation system described above in idle and operation modes. FIGS. 5 to 8 show magnetic field measurements during different vehicle operation statuses. FIG. 5 shows comparison of magnetic field measurements when the vehicle is parked; FIG. 6 shows comparison on magnetic field measured during slow driving of the vehicle; FIG. 7 shows a comparison of magnetic field measured during urban driving within a city; and FIG. 8 shows magnetic field measured during intercity driving. To provide cancellation magnetic field, two parallel electric wire loops were placed in the vehicle. A first loop is placed to overlap a CCL formed by splitting of twisted wire pair transmitting electricity from a high voltage battery to a voltage converting arrangement within the vehicle. The first loop generally corresponds with parallel electrical wire loops 530a illustrated in FIG. 1B. A second loop extends to overlap with CCL connecting a low voltage battery unit with the voltage converting arrangement of the vehicle. The second loop corresponds with parallel electrical wire loops 530b illustrated in FIG. 1B. As described above, the second loop includes a path in which electrical current is transmitted through a portion of the vehicle chassis.

In more details, FIG. 5 shows magnetic fields measured in the rear seat of the vehicle when the vehicle is standing still, when the vehicle is turned on and in parking gear. As shown, when the magnetic field cancelation system MFC described above is turned off (MFC OFF) the magnetic field in the passenger seat is measured at 20-25 mG. The magnetic field measured with the system turned on (MFC ON) is found to be in the range of 2.5-7 mG, mostly in the range 2.5-3 mG. FIG. 6 shows similar results measured during slow driving, in which the vehicle is operated using the electric motor. The measured magnetic field was reduced by operation of the present technique from 20-25 mG to about 4 mG.

In FIGS. 7 and 8, the magnetic fields were measured during driving in real lie environments. FIG. 7 shows measurements taken during urban driving showing that magnetic field was reduced from 20-25 mG, with peaks in the range of 25-30 mG to about 4 mG with peaks of 7-8 mG. FIG. 8 shows magnetic field values measured during intercity and highway driving. As shown, during relative high-speed driving, the magnetic field was measured at 15-23 mG with peaks of about 27 mG with the system turned off. When the system was turned on, it provides reduction in magnetic field to about 5-7 mG. This situation may be different in electric vehicles that rely only on electric motors, keeping in mind that some electric motors may operate with electric current of varying frequency, such that increase frequency is directed to rotate the motor at higher speed, leading to greater vehicle speed.

Generally, the magnetic field measurement device used provides measurements of magnetic field over time. The results show relate to magnitude of the magnetic field vector determined based on magnitude of the field measured in three orthogonal axes over time. The magnetic field measurement device operates with an impulse response providing a band-pass filter for a range between a few Hz o a few KHz. Accordingly, the measured magnetic fields relate to AC components (i.e., frequencies above 0 Hz).

Accordingly, the present disclosure provides a system and a technique suitable for eliminating, or at least significantly reducing magnetic fields generated by electrical currents in a system. The present technique is specifically adapted for operating in electric or hybrid electric vehicles, reducing magnetic and electromagnetic fields at the passenger seating regions of the vehicle. As indicated above, the present technique is based on inventor's understanding of arrangement of current carrying loops within the electrical system, and the role of such current carrying loops in generation of magnetic fields in vicinity of the system.

1-14. (canceled)

15. A motorized vehicle, comprising:
a vehicle chassis;
a passenger region of the motorized vehicle;
at least one current carrying loop (CCL) configured to carry electricity during vehicle operation, thereby generating a magnetic field configured to radiate toward the passenger region;
a current sensor associated with the at least one CCL for sensing current passing through the at least one CCL;
at least one electrical wire loop spatially aligned with a physical path of the at least one CCL; and
at least one circuit configured to:
receive current sensing data from the current sensor, and
based on the current sensing data, determine a cancellation electrical current for providing to the electrical wire loop in order to cause a cancelling magnetic field, thereby at least reducing magnetic radiation from the at least one CCL to the passenger region.

16. The motorized vehicle of claim 15, wherein the magnetic field is an electromagnetic field.

17. The motorized vehicle of claim 15, wherein the at least one CCL includes at least two CCLs.

18. The motorized vehicle of claim 15, wherein the at least one CCL includes a portion of the vehicle chassis, and wherein the electrical wire loop is aligned with a current transmission path through the vehicle chassis.

19. The motorized vehicle of claim 15, wherein the at least one CCL includes a portion of a body of the motorized vehicle.

20. The motorized vehicle of claim 15, wherein the at least one CCL includes an electrical component of the motorized vehicle.

21. The motorized vehicle of claim 15, wherein the at least one CCL includes a cable.

22. The motorized vehicle of claim 15, wherein the at least one CCL is configured to carry current in a first direction and wherein the electrical wire loop is configured to carry current in a second direction, opposite the first direction.

23. The motorized vehicle of claim 15, wherein the current sensor includes at least one of a current clamp, a field probe, or a Rogowski coil.

24. The motorized vehicle of claim 23, wherein the current clamp has a phase shift below a predetermined threshold.

25. The motorized vehicle of claim 15, wherein the current sensor includes a difference current sensor for providing difference sensing data indicative of a difference between current transmitted in the electrical wire loop and the cable.

26. The motorized vehicle of claim 25, wherein the at least one circuit is configured to adjust the cancellation electrical current to minimize the difference sensing data.

27. The motorized vehicle of claim 15, wherein the cancellation electrical current is similar in magnitude and opposite in phase to the current passing through the at least one CCL.

28. The motorized vehicle of claim 15, further comprising a frequency filter configured for filtering the current data and providing filtered data indicative of a plurality of frequency components of the current passing through the at least one CCL, wherein determining the cancellation electrical current includes determining the plurality of frequency components from the filtered data.

29. A method for cancelling a magnetic field in a passenger region of a motorized vehicle, the method comprising:
receiving current data from a current sensor, wherein the current sensor is associated with at least one current carrying loop (CCL) configured to carry electricity during vehicle operation thereby generating a magnetic field configured to radiate into the passenger region, wherein the current sensor is configured to sense current passing through the at least one CCL;
based on the received current data, determining a cancellation electrical current for providing to an electrical wire loop spatially aligned with a physical path of the at least one CCL in order to cause a cancelling magnetic field, to thereby at least reduce magnetic radiation from the at least one CCL to the passenger region of the motorized vehicle; and
providing the cancellation electrical current to the electrical wire loop.

30. The method of claim 29, wherein the current data includes difference sensing data indicative of a difference between current transmitted in the electrical wire loop and the cable.

31. The method of claim 30, further comprising adjusting the cancellation electrical current to minimize the difference sensing data.

32. The method of claim 29, wherein the determined cancellation current is similar in magnitude and opposite in phase to the current passing through the at least one CCL.

33. The method of claim 29, further comprising providing filtered data indicative of a plurality of frequency components of the current passing through the at least one CCL, and wherein determining the cancellation electrical current includes determining the plurality of frequency components from the filtered data.

34. A non-transitory computer-readable memory containing computer-readable instructions that when executed by at least one processor to perform operations for cancelling a magnetic field in a passenger region of a motorized vehicle, the operations comprising:
receiving current data from a current sensor, wherein the current sensor is associated with at least one current carrying loop (CCL) configured to carry electricity during vehicle operation thereby generating a magnetic field configured to radiate into the passenger region, wherein the current sensor is configured to sense current passing through the at least one CCL;
based on the received current data, determining a cancellation electrical current for providing to an electrical wire loop spatially aligned with a physical path of the at least one CCL in order to cause a cancelling magnetic field, to thereby at least reduce magnetic radiation from the at least one CCL to the passenger region of the motorized vehicle; and
causing the cancellation electrical current to be provided to the electrical wire loop.
